(19) United States
(12) Patent Application Publication
(10) Pub. No.: US 2015/0280682 A1
(43) Pub. Date: Oct. 1, 2015

(54) CIRCUIT PROTECTION DEVICE

(71) Applicant: INNOCHIPS TECHNOLOGY CO., LTD., Ansan-Si (KR)

(72) Inventors: In Kil PARK, Seongnam-Si (KR); Tae Hyung NOH, Siheung-Si (KR); Myung Ho LEE, Ansan-Si (KR); Jung Hun LEE, Ansan-Si (KR); Byong Moon NAM, Siheung-Si (KR); Hyun Mo KANG, Ansan-Si (KR); Song Yeon LEE, Ansan-Si (KR); Jin Hwan KIM, Gyeongsangnam-Do (KR)

(21) Appl. No.: 14/672,089

(22) Filed: Mar. 27, 2015

(30) Foreign Application Priority Data
Mar. 28, 2014 (KR) 10-2014-0036831

(51) Int. Cl. H03H 7/01; H01F 27/28; H01F 27/24; H05F 3/04

(52) U.S. Cl. CPC H03H 7/17; H05F 3/04; H01F 27/2804; H01F 27/24

(57) ABSTRACT

A circuit protection device includes a plurality of sheets stacked in a vertical direction, each of which may include at least two conductive patterns formed separately from each other in a horizontal direction, and at least two common mode noise filters disposed in the horizontal direction, each of which includes at least two conductive patterns connected in the vertical direction.

### CROSS-REFERENCE TO RELATED APPLICATION

This application claims priority to Korean Patent Application No. 10-2014-0036831 filed on Mar. 28, 2014 and all the benefits accruing therefrom under 35 U.S.C. §119, the contents of which are incorporated by reference in their entirety.

### BACKGROUND

The present disclosure relates to a circuit protection device, and more particularly to a circuit protection device capable of suppress noise of a plurality of frequency bands and reducing a mounting area.

As media and culture contents are diversified and qualities of images and sounds are continuously improved, a data amount that electronic devices have to transmit is rapidly increased. For the data transmission specification, for example, a universal serial bus (USB) 2.0 specification has been widely used until recent days. Although the USB 2.0 speed of 480 Mbps is sufficiently rapid before high quality video contents are mainly consumed, nowadays it is as slow as the users feel inconvenience.

On the contrary, USB 3.0 speed of 5.0 Gbps is faster ten times than that of USB 2.0 and is suitable specification for transmission of high quality contents currently consumed. The USB 3.0 is first applied to a PC and external storage medium (e.g., an external hard disk, a USB memory stick, etc.) and recently a function thereof is mounted in a smart phone. Since a smart phone includes a high quality LCD and a function of a camera capable of capturing a high quality image, USB 3.0 mount is a natural flow. The USB 3.0 function is being mounted in an expensive smart phone and is expected to be gradually mounted in middle-low priced smart phone.

When the USB 3.0 is mounted in an electronic device, it is not to replace the existing USB 2.0 but to additionally install a USB 3.0 related chip set inside the device with the USB 2.0 being inside the device and to increase the number of pins of a connector connected to the outside to allow the USB 2.0 and the USB 3.0 to be simultaneously available. In terms of the number of data lines, while the existing USB 2.0 has two lines, the USB 3.0 has four lines and accordingly a device having the USB 3.0 function mounted therein requires that total six USB data lines are to be installed inside the electronic device. Typically when performing USB communication, since a USB signal is radiated to play as a noise source of electromagnetic interference (EMI) to other electronic devices or other circuits inside the electronic device, an EMI filter is typically installed in USB lines. When the USB 3.0 is added, total three EMI filters are required for the data lines and total six lines, namely, filters are installed in three pairs for each pair. In other words, three filters are necessary for every two lines, namely, total six lines. As the filter, a common mode noise filter having a structure that two choke coils are integrated into one may be used. An example of the common mode noise filter is disclosed in Korean Patent No. 10-0876206.

However, unlike the typical device, since a smart phone has a narrow printed circuit board area, when three filters are additionally installed, a mount area becomes larger. In addition, sine the USB 2.0 and USB 3.0 has a difference in transmission speed of ten times or greater, a cutoff frequency characteristic of the filter becomes differed.

### SUMMARY

The present disclosure provides a circuit protection device capable of reducing a mount area.

The present disclosure also provides a circuit protection device having at least two cutoff frequencies while a mount area is reduced.

The present invention also provides a circuit protection device capable of being mounted in a USB 2.0 line and USB 3.0 line to respectively suppress noises thereof.

In accordance with an exemplary embodiment, a circuit protection device includes: a plurality of sheets stacked in a vertical direction, each of which may include at least two conductive patterns formed separately from each other in a horizontal direction; and at least two common mode noise filters disposed in the horizontal direction, each of which includes at least two conductive patterns connected in the vertical direction.

The conductive pattern may include a coil pattern, a straight line pattern, and a curved pattern.

The at least two coil patterns formed in the horizontal direction may include at least two turns.

The plurality of sheets may further include at least two holes with a conductive material buried therein and at least two first withdrawal electrodes respectively connected to the at least two conductive patterns.

The conductive patterns may be connected in the vertical direction through the holes with the conductive material buried therein.

The plurality of sheets may include first to fourth sheets each of which includes the at least two holes with the conductive material buried therein, the two at least conductive patterns, and the at least two first withdrawal electrodes, wherein the conductive patterns on the first sheet may be respectively connected to the conductive patterns of the third sheet through the holes formed in the first and second sheets, the conductive patterns on the second sheet may be respectively connected to the conductive patterns on the fourth sheet through the holes formed in the second and third sheets, and any one of the conductive patterns connected vertically may be a coil pattern.

At least any one of the coil patterns may include a greater number of turns than other coil patterns.

The plurality of sheets may include first to fourth sheets each of which may include first to third coil patterns including at least two turns, wherein the first to third coil patterns on the first sheet may be respectively connected to the first to third coil patterns on the third sheet through the holes formed in the first and second sheets, and the first to third coil patterns on the second sheet may be respectively connected to the first to third coil patterns on the fourth sheet through the holes formed in the second and third sheets

The first and third coil patterns may include an identical number of turns and the second coil pattern may include a greater number of turns than the first and third coil patterns.

The first to third coil patterns may be vertically connected to respectively form first to third common mode noise filters, and the first and third common mode noise filter may be connected to a USB 3.0 line connected to a USB 3.0 chipset and the second common mode noise filter may be connected to a USB 2.0 line connected to a USB 2.0 chipset.

The first and third common mode noise filters may include a cutoff frequency of approximately 7 GHz to 9 GHz in a differential mode and the second common mode noise filter may include a cutoff frequency of approximately 4 GHz to 5 GHz in a differential mode.

The first and third common mode noise filters may include a cutoff frequency of approximately 2 GHz in a common mode and the second common mode noise filter may include a cutoff frequency of approximately 1 GHz in a common mode.

The circuit protection device may further include at least two first external electrodes disposed on two opposite side surfaces of a stacked body in which the plurality of sheets may be stacked, and connected to the at least two first withdrawal electrodes.

The circuit protection device may further include a magnetic core formed in a center of at least one coil pattern of the common mode noise filter.

The circuit protection device may further include an ESD protection device disposed at a bottom side of the at least one common mode noise filter and configured to protect an ESD.

The ESD protection device may include a plurality of holes with an ESD protection material buried therein and at least two second withdrawal electrodes formed in an identical direction to that of the at least two first withdrawal electrodes from the holes.

The ESD protection device may further include a third withdrawal electrode formed in a perpendicular direction to that of the second withdrawal electrodes.

The circuit protection device may further include second external electrodes disposed on two opposite side surfaces of the stacked body and connected to the third withdrawal electrodes.

### BRIEF DESCRIPTION OF THE DRAWINGS

Exemplary embodiments can be understood in more detail from the following description taken in conjunction with the accompanying drawings, in which:

FIG. 1 is a combined perspective view of a circuit protection device in accordance with an exemplary embodiment;

FIG. 2 is a combined cross-sectional view of a circuit protection device in accordance with an exemplary embodiment;

FIG. 3 is an explosive perspective view of a circuit protection device in accordance with an exemplary embodiment;

FIG. 4 is a schematic diagram illustrating an installment position of a circuit protection device in accordance with an exemplary embodiment;

FIGS. 5 and 6 are cutoff frequency characteristics according to an exemplary embodiment;

FIG. 7 is a combined perspective view of a circuit protection device in accordance with another exemplary embodiment;

FIG. 8 is a combined cross-sectional view of a circuit protection device in accordance with still another exemplary embodiment; and

FIG. 9 is a combined perspective view of a circuit protection device in accordance with still another exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the thickness and dimensions of layers and regions are exaggerated for clarity of illustration. Like reference numerals refer to like elements throughout.

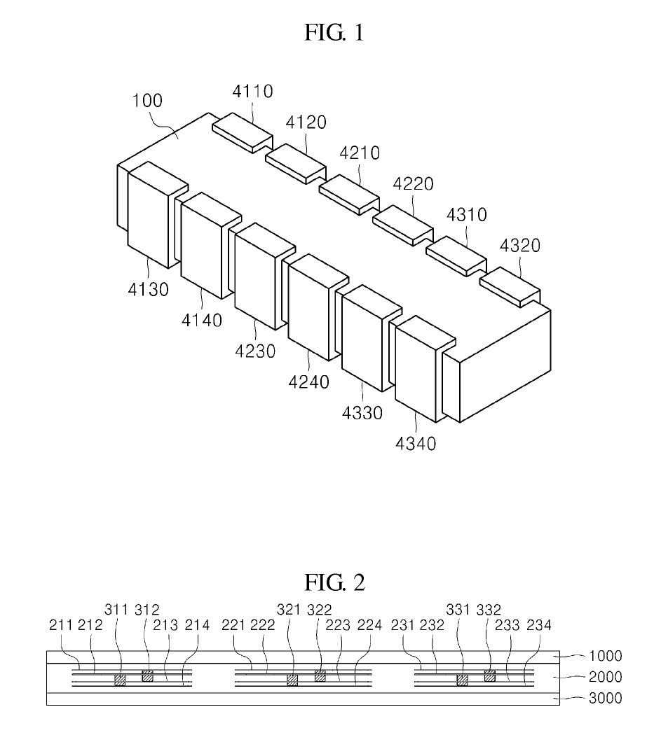

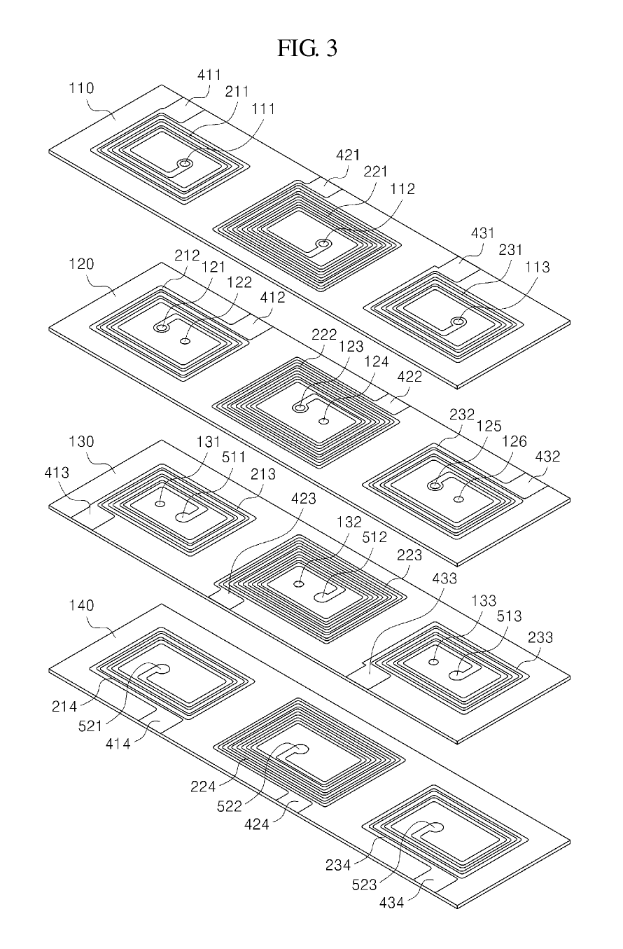

FIG. 1 is a combined perspective view of a circuit protection device in accordance with an exemplary embodiment, FIG. 2 is a cross-sectional view, and FIG. 3 is an explosive perspective view.

A circuit protection circuit according an exemplary embodiment is, as illustrated in FIG. 1, configured with a stacked body 100 in which a plurality of insulation sheets are stacked, and includes, as illustrated in FIGS. 2 and 3, a top cover layer 1000, at least two common mode noise filters 2000 (2100, 2200, and 2300), and a bottom cover layer 3000 from the top. In addition, the circuit protection circuit may further include external electrodes 4000 (4100, 4200, and 4300) formed two opposite side surfaces and connected to at least two common mode noise filter 2000.

The top cover layer 1000 and the bottom cover layer 3000 may be respectively disposed in a manner that a plurality of rectangular magnetic material sheets are stacked. At this point, the magnetic material sheet may have a length ratio of a short side to a long side of, for example, 1:3. In addition, the top cover layer 1000 and bottom cover layer 3000 may be disposed to have an identical thickness, and may be thinner than the common mode noise filter 2000 disposed therebetween. However, the top cover layer 1000, the common mode noise filter 2000, and the bottom cover layer 3000 may be also disposed to have an identical thickness or different thicknesses.

The common mode noise filter 2000 is disposed between the top cover layer 1000 and the bottom cover layer 2000. The common mode noise filter 2000 may have a plurality of sheets 110 to 140 stacked, and include a plurality of coil patterns, holes with a conductive material buried therein, and withdrawal electrodes formed on the plurality of sheets 110 to 140. In other words, at least two coil patterns are formed on the top portion of the plurality of sheets 110 to 140, at least two coil patterns in a stacked direction of the sheets, namely, in a vertical direction are connected through the holes with the conductive material buried therein, namely, vertical interconnections. Accordingly, the plurality of coil patterns connected in the vertical direction form the one common mode noise filter 2000, and accordingly at least two common mode noise filters 2100, 2200, and 2300 are formed in a horizontal direction. In other words, at least two common mode noise filters 2000 are disposed in one circuit protection device, and in the present embodiment, a case where three common mode noise filters 2100, 2200, and 2300 are formed is exemplarily described. Here, at least two coil patterns 211, 221, and 231 and a plurality of holes 111, 112, and 113 having the conductive material buried therein are formed on the first sheet 110, and at least two coil patterns 212, 222, and 232 and a plurality of holes 121, 122, 123, 124, 125, and 126 having the conductive material buried therein are formed on the second sheet 120, at least two coil patterns 213, 223, and 233 and a plurality of holes 131, 132, and 133 having the conductive material buried therein are formed on the third sheet 130, and at least two coil patterns 214, 224, and 234 are formed on the fourth sheet 140.

In addition the at least two coil patterns 211, 221, and 231 formed on the first sheet 110 are respectively connected to the at least two coil patterns 213, 223, and 233 formed on the third sheet 130 through the plurality of holes 111, 112, and 113 with the conductive material buried therein formed on the first sheet 110, and a plurality of holes 122, 124, and 126 having the conductive material buried therein formed on the second sheet 120, and the at least two coil patterns 212, 222, and 232 formed on the second sheet 120 are respectively connected to the at least two coil patterns 214, 224, and 234 formed on the fourth sheet 140 through the plurality of holes 121, 123, and 125 with the conductive material buried therein formed on the second sheet 120, and a plurality of holes 131, 132, and 133 having the conductive material buried therein formed on the third sheet 130. In other words, the coil pattern 211 of the first sheet 110 is connected to the coil pattern 213 of the third sheet 130 through the vertical interconnection 311, and the coil pattern 212 of the second sheet 120 is connected to the coil pattern 214 of the fourth sheet 140 through the vertical interconnection 312, so that the first common mode noise filter 2100 is formed. In addition, the coil pattern 221 of the first sheet 110 is connected to the coil pattern 223 of the third sheet 130 through the vertical interconnection 321, and the coil pattern 222 of the second sheet 120 is connected to the coil pattern 224 of the fourth sheet 140 through the vertical interconnection 322, so that the second common mode noise filter 2200 is formed. In addition, the coil pattern 231 of the first sheet 110 is connected to the coil pattern 233 of the third sheet 130 through the vertical interconnection 331, and the coil pattern 232 of the second sheet 120 is connected to the coil pattern 234 of the fourth sheet 140 through the vertical interconnection 332, so that the second common mode noise filter 2300 is formed. Here, the vertical interconnections 311, 312, 321, 322, 331, and 332 are formed by contacting the plurality of holes with the conductive material buried therein. In other words, the common mode noise filters 2000 (2100, 2200, and 2300) may have at least two turns of coil pattern and accordingly have at two impedance characteristics. In other words, the first and third common mode noise filters 2100 and 2300 may be connected to the USB 2.0 line and the second common mode noise filter 2200 may be connected to the USB 2.0 line. The first and third common mode noise filters 2100 and 2300 may have identical numbers of turns of coil pattern, and may have different number of turns of coil pattern from the second common mode noise filter 2200. For example, the numbers of turns of coil pattern of the first and third common mode noise filters 2100 and 2300 may be equal to or smaller than that of the second common mode noise filter 2200, and a ratio of the numbers of turns of coil patterns may be, for example, 1:1 to 1:10.

The external electrodes 4000 may be disposed on a first side surface and a second side surface opposite thereto of the stacked body 100. In other words, when a stacked direction of the sheets is referred to a vertical direction, the external electrodes 4000 may be formed two opposite long side surfaces in the horizontal direction of the stacked body 1000. In addition, the external electrodes 4000 may be disposed on first and second side surfaces for each of at least two common mode noise filters 2100, 2200, and 2300. Accordingly, six external electrodes 4000 may be formed on the first and second side surfaces for three common mode noise filters 2100, 2200, and 2300. In other words, the first external electrodes 4110, 4120, 4130, and 4140 connected to the first common mode noise filter 2100, the second external electrodes 4210, 4220, 4230, and 4240 connected to the second common mode noise filter 2200, and the third external electrodes 4310, 4320, 4330, and 4340 connected to the third common mode noise filter 2300 may be included. These external electrodes 4000 may be respectively connected between an input terminal and an output terminal. In other words, the external electrodes 4000 formed on one side surface of the circuit protection device may be connected to a signal input terminal, and the external electrodes 400 formed on another side corresponding thereto may be connected to an output terminal, for example, a system.

Furthermore, in the foregoing embodiment, the two upper and lower coil patterns in a spiral form are connected to form one inductor, but one conductive pattern implementing an inductor is formed as a coil pattern in the spiral form and another conductive pattern connected to the one conductive pattern in the vertical direction may have various forms such as a straight line type and a curved type. In other words, in the common mode noise filter of the embodiment, two conductive patterns are vertically connected to form an inductor, at least one of the two conductive patterns may have a spiral form, and at this point, the other one may have another form, not the spiral form.

The common mode noise filter of the circuit protection device according to an embodiment will be described in detail with reference to an explosive perspective view of FIG. 3.

As illustrated in FIG. 3, the common mode noise filter 20 may include the plurality of sheets 110 to 140, the plurality of holes 111, 112, 113, 121, 122, 123, 124, 125, 126, 131, 132, and 133 selectively formed on the plurality of sheets 110 to 140 with the conductive material buried therein, the plurality of coil patterns 211, 221, 231, 212, 222, 232, 231, 232, 233, 241, 242, and 243 formed on the sheets 110, 120, 130, and 140, a plurality of withdrawal electrodes 411, 421, 431, 412, 422, 432, 413, 423, 433, 414, 424, and 434 formed on the sheets 110, 120, 130, and 140 and connected to the plurality of coil patterns 211, 221, 231, 212, 222, 232, 231, 232, 233, 241, 242, and 243 formed on the sheets 110, 120, 130, and 140, and connected to a plurality of withdrawal electrodes 411, 421, 431, 412, 422, 432, 413, 423, 433, 414, 424, and 434 to be withdrawn externally. Detailed description will be provided about a configuration of the common mode noise filter 2000 as follows.

The plurality of holes 111, 112, and 113, the plurality of coil patterns 211, 221, and 231, and the withdrawal electrodes 411, 421, and 431 are formed on the first sheet 110. The sheet 110 may be disposed in a substantially rectangular plate form having a predetermined thickness, and may be disposed so that a short side and a long side have a length ratio, for example 1:3. In other words, the sheet 110 may have a rectangular form that the long side is, for example, three times longer than the short side. The plurality of holes 111, 112, and 113 may be formed in a separated manner in a long side direction, at a predetermined area of the sheet 110, for example, at a central area of the short side to penetrate the first sheet 110. At this point, an interval between the holes 111, 112, and 113 may be formed identically. A conductive material is buried in the holes 111, 112, and 113 by using a paste of metal material. The holes 111, 112, and 113 with the conductive material buried become a part of the vertical interconnections 312, 322, and 332. In addition, the plurality of coil patterns 211, 221, and 231 may be formed in the spiral form by, for example, printing the conductive material, and may be formed with the predetermined number of turns by rotating in one direction from each of the plurality of holes 111, 112 and 113. At this point, the plurality of coil patterns 211, 221, and 231 may rotate for each of the plurality of holes 111, 112, and 113, for example, in clockwise direction in order to be separated from each other in a predetermined interval. Accordingly, the plurality of coil patterns 211, 221, and 231 are extended from the holes 111, 112, and 113 in one direction, for example, in a long side direction and formed by rotating by the plurality number of turns along a periphery of the holes 111, 112, and 113 and an area in which the holes 121, 123, and 125 of the second sheet 120 are formed. At this point, the plurality of coil patterns 211, 221, and 231 may be formed to have an identical line width and an interval and at least any one may be different. In addition, the plurality of coil patterns 211, 221, and 231 may have identical number of turns or at least any one may be different. For example, the second coil pattern 221 may have the greater number of turns than those of the first and third coil patterns 211 and 231, and for example, may have a ratio of number of turns of 1:1 to 10:1. In addition, one end of the plurality of coil patterns 211, 221, and 231 are connected to the withdrawal electrodes 411, 421, and 431. The withdrawal electrodes 411, 421, and 431 are formed with a predetermined width to be exposed to one long side of the first sheet 110. For example, the withdrawal electrodes 411, 421, and 431 are formed to be exposed to one long side of the first sheet 110, which is in an opposite direction to a direction that the coil patterns 211, 221, and 231 are extended from the plurality of holes 111, 112, and 113 of the first sheet 110.

The plurality of holes 121, 122, 123, 124, 125, and 126, the plurality of coil patterns 212, 222, and 232, and the withdrawal electrodes 412, 422, and 432 are formed on the second sheet 110. The second sheet 120 may be disposed in a rectangular plate form having identical thickness and form to the first sheet 110. The plurality of holes 121, 122, 123, 124, 125, and 126 may be formed in a separated manner in a long side direction, at a predetermined area of the sheet 124, for example, at a central area of the short side to penetrate the second sheet 120. At this point, the holes 122, 124 and 126 may be formed at an identical position as the holes 111, 112, and 113 of the first sheet 110. In addition, the holes 121, 123, and 125 may be formed separately from the holes 122, 124, and 126 by a predetermined interval. The holes 121, 122, 123, 124, 125, and 126 may be buried by, for example, a paste of metal material. In addition, the holes 122, 124 and 126 may be connected with the conducted material buried in the holes 111, 112, and 113 of the first sheet 110 by the conductive material. Accordingly, the holes 122, 124, and 126 may become a part of the vertical interconnections 312, 322, and 323. In addition, the holes 121, 123, and 125 with the conductive material buried become a part of the vertical interconnections 311, 321, and 331. Each of the plurality of coil patterns 212, 222, and 232 may rotate in one direction from the holes 121, 123, and 125 to be formed in the predetermined number of turns. At this time, the plurality of coil patterns 212, 222, and 232 may be formed not to pass the holes 122, 124, and 126. Accordingly, the plurality of coil patterns 212, 222, and 232 may be extended, for example, in one long side direction from the holes 121, 123, and 125, and formed by rotating by the plurality number of turns along a periphery of an area in which the holes 121, 122, 123, 124, 125, and 126 are formed therefrom. At this point, the plurality of coil patterns 212, 222, and 232 may be formed to have an identical line width and interval and at least any one may be differed. In addition, the plurality of coil patterns 212, 222, and 232 may be formed to have an identical number of turns and at least any one may be differed. For example, the second coil pattern 222 may have greater number of turns than those of the first and third coil patterns 212, and 232, and may have a ratio of turns, for example, 1:1 to 10:1. In addition, each of the coil patterns 212, 222, and 232 formed on the second sheet 120 may rotate in an identical direction to that of the coil patterns 211, 221, and 231 formed on the first sheet 110 corresponding thereto and may have the identical number of turns. Furthermore, one ends of the plurality of coil patterns 212, 222, and 232 are connected to the withdrawal electrode 412, 422, and 432. The withdrawal electrodes 412, 422, and 432 are formed in a predetermined width to be exposed to one side of the second sheet 120. At this point, the withdrawal electrodes 412, 422, and 432 may be separated in a predetermined interval from the withdrawal electrodes 411, 421, and 431 formed on the first sheet 110 and formed to be exposed to an identical direction.

The plurality of holes 131, 132, and 133, the plurality of coil patterns 213, 223, and 233, and the plurality of horizontal interconnections 511, 512 and 513 are formed on the third sheet 130. The third sheet 130 may be disposed in a rectangular plate form having identical thickness and form to the first and second sheets 110 and 120. The plurality of holes 131, 132, and 133 may be formed by penetrating the third sheet 130m and may be formed at identical positions to the holes 121, 124, and 125 of the second sheet 120. In addition, the plurality of holes 131, 132, and 133 may be buried by using a paste of metal material. Accordingly, the holes 131, 132, and 133 are connected to the holes 121, 123, and 125 of the second sheet 120 to become a part of the vertical interconnections 311, 321, and 331. The horizontal interconnections 511, 512, and 513 may be formed separately by a predetermined distance from the holes 131, 132 and 133 and at identical positions to the holes 122, 125 and 126 of the second sheet 120. In addition, the plurality of coil patterns 413, 423, and 433 may rotate in one direction from the plurality of interconnections 511, 512, and 513 and may be formed in a predetermined number of turns. At this point, the plurality of coil patterns 413, 423 and 433 may be formed not to pass the holes 131, 132, and 133 formed on the third sheet 130 and the interconnections 511, 512, and 513. Accordingly, the plurality of coil patterns 213, 223, and 233 may be extended, for example, in one long side direction from the horizontal interconnections 511, 512, and 513, and formed by rotating in the plurality number of turns along a periphery of an area in which the holes 131, 132, 133, and the horizontal interconnections 511, 512, and 513 are formed therefrom. At this point, the plurality of coil patterns 213, 223, and 233 may be formed to have an identical line width and interval and at least any one may be differed. In addition, the plurality of coil patterns 213, 223, and 233 may be formed to have an identical number of turns and at least any one may be differed. For example, the second coil pattern 223 may have greater number of turns than those of the first and third coil patterns 213, and 233, and may have a ratio of turns, for example, 1:1 to 10:1. In addition, the coil patterns 213, 223, and 233 formed on the third sheet 130 rotate in an identical direction with an identical number of turns to the coil patterns 211, 221, and 231 formed on the first sheet 110 and the coil patterns 212, 222, and 232 formed on the second sheet 120 respectively corresponding thereto. Furthermore, one ends of the plurality of coil patterns 213, 223, and 233 are connected to the withdrawal electrodes 413, 423 and 433. The withdrawal electrodes 413, 423, and 433 are formed to have a predetermined width to be exposed to one side of the third sheet 130. At this point, the withdrawal electrodes 413, 423, and 433 may be formed to have an identical width at an identical position to and in a different direction from the withdrawal electrodes 411, 421, and 431 formed on the first sheet 110.

The plurality of coil patterns 214, 224, and 234, the plurality of horizontal interconnections 521, 522 and 523, and the plurality of withdrawal electrodes 414, 424, and 434 are formed on the fourth sheet 140. The fifth sheet 140 may be disposed in a substantially rectangular plate form having a predetermined thickness and disposed in an identical form to those of the sheets 110, 120, and 130. The horizontal interconnections 521, 522, and 523 may be separated in one direction to be formed on a predetermined area of the fourth sheet 140. For example, the plurality of horizontal interconnections 521, 522, and 523 may be formed on an identical area to that of the plurality of holes 131, 132, and 133 of the third sheet 130. In addition, the plurality of coil patterns 214, 224, and 234 may rotate in one direction from the plurality of interconnections 521, 522, and 523 and may be formed in a predetermined number of turns. At this point, the plurality of coil patterns 214, 224, and 234 may be formed not to pass the interconnections 521, 522, and 523 on the fourth sheet 140 and the periphery thereof. For example, the plurality of coil patterns 214, 224, and 234 are extended from the interconnections 521, 522, and 523 in one direction, for example, one long side direction, and may be formed to have identical forms to the plurality of coil patterns 213, 223, and 233 formed on the third sheet 130. At this point, the plurality of coil patterns 214, 224, and 235 may be formed to have an identical width and interval and at least any one may be differed. In addition, the plurality of coil patterns 214, 224, and 234 may have identical number of turns and at least any one may be differed. For example, the second coil patterns 224 may have greater number of turns that those of the first and third coil patterns 214 and 234, and may have a ratio of number of turns, for example, 1:1 to 10:1. Furthermore, one ends of the plurality of coil patterns 214, 224, and 234 are connected to the withdrawal electrodes 414, 424, and 434. The withdrawal electrodes 414, 424, and 434 are formed to have a predetermined width to be exposed to one side of the fourth sheet 140. At this time, the withdrawal electrodes 412, 422, and 432 formed on the second sheet 120 may be formed in an opposite direction to the withdrawal electrodes 412, 422, and 432 formed on the second sheet 120 and at an identical position.

As described above, in the circuit protection device according to an embodiment, the plurality of coil patterns 211, 221, and 231 formed on the first sheet 110 are respectively connected to the plurality of coil patterns 213, 223, and 233 formed on the third sheet 130 through the plurality of holes 111, 112, and 113 with a conductive material buried therein formed on the first sheet 110 and the plurality of holes 122, 124, and 126 with a conductive material buried therein formed on the second sheet 120, and the plurality of coil patterns 212, 222, and 232 formed on the second sheet 120 are respectively connected to the plurality of coil patterns 414, 424, and 434 formed on the fourth sheet 140 through the plurality of holes 121, 123, and 125 with a conductive material buried therein formed on the second sheet 120 and the plurality of holes 131, 132, and 133 with a conductive material buried therein formed on the third sheet 130. Accordingly, in the circuit protection device according to an embodiment, the plurality of coil patterns 411, 421, and 431 formed on the first sheet 110, and the plurality of coil patterns 413, 423, and 433 formed on the third sheet 130 are respectively connected to form the plurality of first inductors, and the plurality of coil patterns 421, 422, and 423 formed on the second sheet 120, and the plurality of coil patterns 414, 424, and 434 formed on the fourth sheet 140 are respectively connected to form the plurality of second inductors. The plurality of common mode noise filters 2000 (2100, 2200, and 2300) may be implemented by the first and second inductors formed in a vertical direction. In other words, the first common mode noise filter 2100 includes the first inductor in which the two coil patterns 211 and 213 are connected and the second inductor in which two coil patterns 212 and 214 are connected, the second common mode noise filter 2200 includes the first inductor in which the two coil patterns 221 and 223 are connected and the second inductor in which two coil patterns 222 and 224 are connected, and the third common mode noise filter 2300 include the first inductor in which the two coil patterns 231 and 233 are connected and the second inductor in which two coil patterns 232 and 234 are connected.

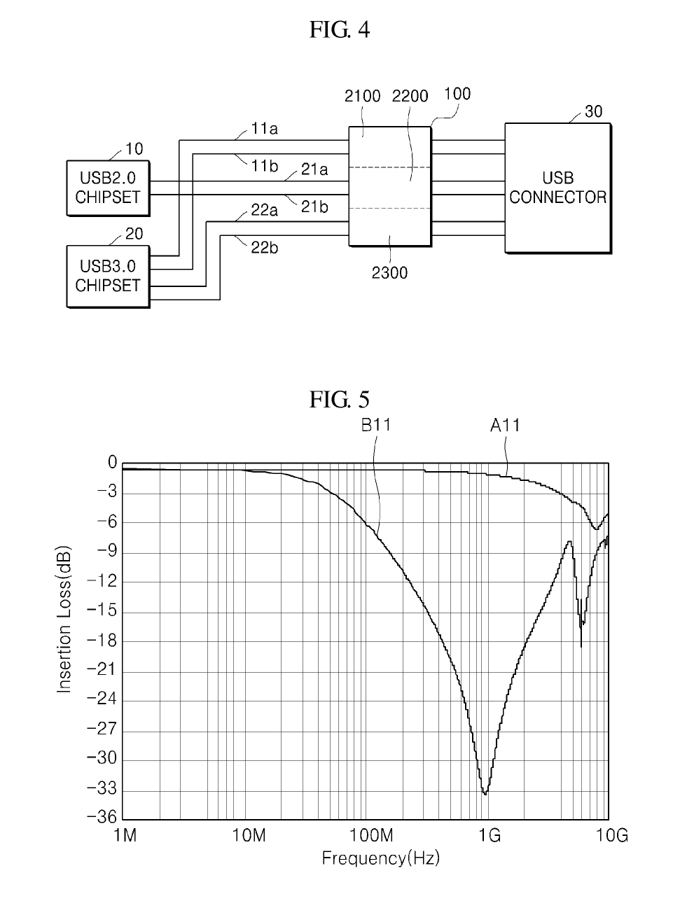

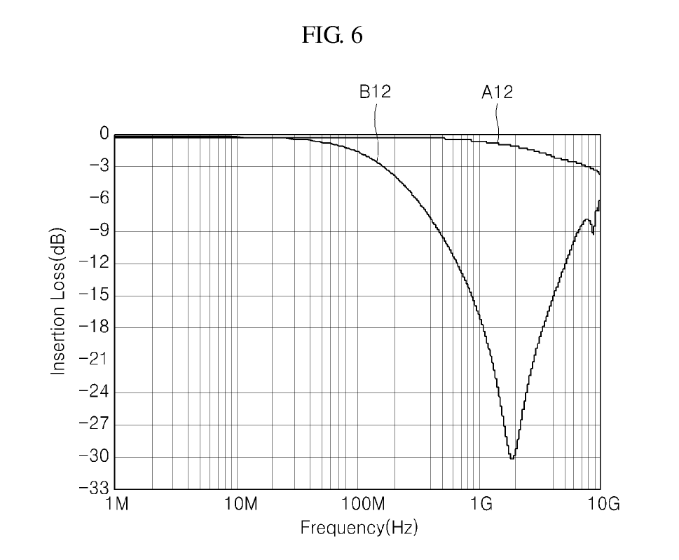

The circuit protection device according to an embodiment may adjust inductance or impedance by adjusting the number of turns of the coil patterns 210, 220, and 230, and accordingly may adjust frequency noise capable of being suppressed. For example, the number of turns of the coil pattern 220 of the second common mode noise filter 2200 is allowed to be greater than those of the coil patterns 210 and 230 of the first and third common mode noise filters 2100 and 2300, as illustrated in FIG. 4, the second common mode noise filter 220 may be connected to the USB 2.0 line, and the first and third common mode noise filters 2100 and 2300 may be connected to the USB 3.0 line. In other words, the second common mode noise filter 2200 is connected to the USB 2.0 lines 11a and 11b between a US 2.0 chipset 10 and a USB connector 30, and the first and third common mode noise filters 2100 and 2300 are connected to the USB 3.0 lines 21a, 21b, 22a, and 22b between a US 3.0 chipset 20 and a USB connector 30. Accordingly, as illustrated in FIG. 5, the second common mode noise filter 2200 has a cutoff frequency characteristic of approximately 45 GHz to 5 GHz at a differential mode A11 and a cutoff frequency characteristic of approximately 1 GHz at a common mode B11. In addition, as illustrated in FIG. 6, the first and third common mode noise filter 2100 and 2300 have a cutoff frequency characteristic of approximately 75 GHz to 9 GHz at a differential mode A12 and a cutoff frequency characteristic of approximately 2 GHz at a common mode B12. In other words, the common mode noise filters 2000 according to an embodiment is connected to the USB line between the USB chipset and USB connector to be used for communication, and in this case, the second common mode noise filter 2200 suppresses noise of approximately 45 GHz to 5 GHz frequency, and the first and third common mode noise filters 2100 and 2300 suppress noise of approximately 75 GHz to 9 GHz frequency at approximately 3 dB differential mode. Finally, the circuit protection device according to an embodiment, two or more frequency band noise can be suppressed and accordingly used for a mobile electronic device such as a smart phone to improve quality of the electronic device.

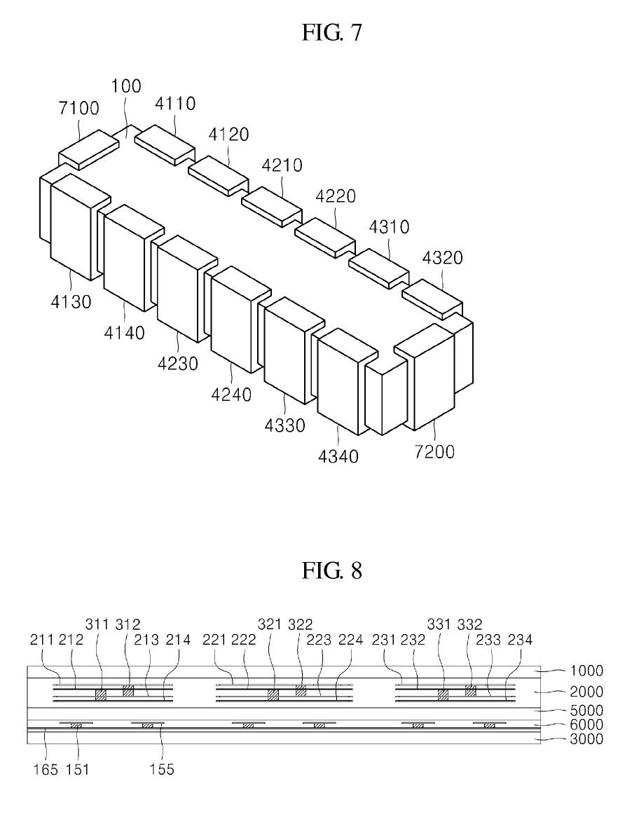

Furthermore the circuit protection device is exemplarily described about a plurality of common mode noise filters respectively formed with two indictors. However, the circuit protection device according to an embodiment may be disposed in a structure in which the plurality of common mode noise filters and an ESD protection device are combined. In other words, at least two common mode noise filters and an ESD protection device are combined to realize the circuit protection device. The circuit protection device according to another embodiment will be described with reference to FIGS. 7, 8 and 9.

FIG. 7 is a combined perspective view of a circuit protection device according to another embodiment, FIG. 8 is a combined cross-sectional view, and FIG. 1 is an explosive perspective view.

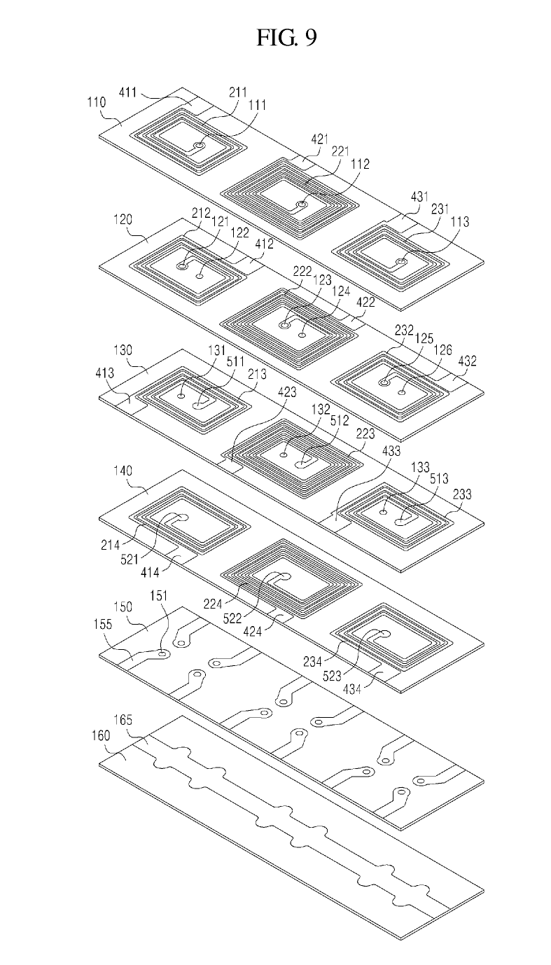

Referring to FIG. 7, a circuit protection device according to another embodiment is formed with a stacked body 100 in which a plurality of insulation sheets, and as illustrated in FIGS. 8 and 9, includes an top cover layer 1000, at least two common mode noise filters 2000 (2100, 2200, and 2300), an intermediate layer 5000, an ESD protection device 6000, and a bottom cover layer 3000. In other words, the common mode noise filter 2000 and ESD protection device 6000 are stacked between the top cover layer 1000 and bottom cover layer 3000 and disposed. In addition, the first external electrodes 4000 (4100, 4200, and 4300) formed on two opposite side surfaces of the stack body 100 and connected to the at least two common mode noise filter 2000 and the ESD protection device 6000, and the second external electrodes 7000 (7100 and 7200) formed on two opposite side surfaces of the stacked body 100 on which the first external electrodes 4000 are not formed and connected to the ESD protection device 6000 may be further included. In other words, the first external electrodes 4000 are formed on two opposite long side surfaces of the stacked body 100 and the second external electrodes 7000 may be formed on two opposite short side surfaces of the stacked body.

The at least two coil patterns 211, 221, and 231 formed on the first sheet 110 are respectively connected to the at least two coil patterns 213, 223, and 233 formed on the third sheet 130 through the plurality of holes 111, 112, and 113 with the conductive material buried therein formed on the first sheet 110, and a plurality of holes 122, 124, and 126 having the conductive material buried therein formed on the second sheet 120, and the at least two coil patterns 212, 222, and 232 formed on the second sheet 120 are respectively connected to the at least two coil patterns 214, 224, and 234 formed on the fourth sheet 140 through the plurality of holes 121, 123, and 125 with the conductive material buried therein formed on the second sheet 120, and a plurality of holes 131, 132, and 133 having the conductive material buried therein formed on the third sheet 130. In other words, the coil pattern 211 of the first sheet 110 is connected to the coil pattern 213 of the third sheet 130 through the vertical interconnection 311, and the coil pattern 212 of the second sheet 120 is connected to the coil patter 214 of the fourth sheet 140 through the vertical interconnection 312, so that the first common mode noise filter 2100 is formed. In addition, the coil pattern 221 of the first sheet 110 is connected to the coil pattern 223 of the third sheet 130 through the vertical interconnection 321, and the coil pattern 222 of the second sheet 120 is connected to the coil pattern 224 of the fourth sheet 140 through the vertical interconnection 322, so that the second common mode noise filter 2200 is formed. In addition, the coil pattern 231 of the first sheet 110 is connected to the coil pattern 233 of the third sheet 130 through the vertical interconnection 331, and the coil pattern 232 of the second sheet 120 is connected to the coil pattern 234 of the fourth sheet 140 through the vertical interconnection 332, so that the second common mode noise filter 2300 is formed. In other words, the common mode noise filters 2000 (2100, 2200, and 2300) may have at least two turns of coil pattern and accordingly have at two impedance characteristics. In other words, the first and third common mode noise filters 2100 and 2300 may be connected to the USB 3.0 line and the second common mode noise filter 2200 may be connected to the USB 2.0 line. The first and third common mode noise filters 2100 and 2300 may have identical numbers of turns of coil pattern, and may have different number of turns of coil pattern from the second common mode noise filter 2200. For example, the numbers of turns of coil pattern of the first and third common mode noise filters 2100 and 2300 may be equal to or smaller than that of the second common mode noise filter 2200, and a ratio of the numbers of turns of coil pattern may be, for example, 1:1 to 1:10. The configuration of the common mode noise filter is identical to an embodiment described in relation to FIGS. 2 and 3, and detailed description thereabout will be omitted

The ESD protection device 6000 is configured by stacking the plurality of sheets 150 and 160 in which the withdrawal electrode and holes are selectively formed.

The plurality of withdrawal electrodes 155 are formed on the top surface of the sheet 150. The plurality of withdrawal electrodes 155 may be formed at identical position to the withdrawal electrodes 400 of the plurality of common mode noise filter 2000. In other words, the plurality of withdrawal electrodes 155 of the ESD protection device 6000 may be formed to correspond to the plurality of withdrawal electrodes 400 of the plurality of common mode noise filter 2000. Accordingly, the withdrawal electrodes 155 are connected to the first external electrodes 4000 together with the withdrawal electrodes 400 of the plurality of common mode noise filters 2000. In addition, the plurality of holes 151 are formed on the sheet 150, and the plurality of holes 151 may be formed on end portion of the plurality of withdrawal electrodes 155, respectively. In addition, the plurality of holes 151 are buried with an ESD protection material. The ESD protection material may be formed of a material in which at least one conductive material selected from among RuO₂, Pt, Pd, Ag, Au, Ni, Cr, and W to an organic material such as Polyvinyl Alcohol (PVA) or Polyvinyl Butyral (PVB). In addition, the ESD protection material may be formed by further mixing a barrister material ZnO or an insulation ceramic material such as Al₂O₃ to the foregoing mixed material.

The withdrawal electrodes 165 exposed in a short side direction of the sheet 160 are formed on the top surface of the sheet 160. The withdrawal electrodes 165 may be formed from one short side of the sheet 160 to the other side opposite thereto along a long side. In other words, the withdrawal electrodes 165 are extended and formed to be exposed to one short side and the other short side along the long side. The withdrawal electrodes 165 are connected to the second external electrodes 7000 formed on two opposite short side surfaces. In addition, a predetermined area of the withdrawal electrodes 160 is connected to the holes 161 and to this end, the area connected to the holes 161 may be formed to have wider width than other areas.

The ESD protection device 6000 is in a state where the ESD protection material buried in the holes 151 is mixed with the conductive material and insulation material in a predetermined ratio. In other words, conductive particles are present between the insulation materials. When a voltage smaller than a predetermined voltage is applied to the withdrawal electrodes 155, the insulation state is maintained. When a voltage of a predetermined voltage or greater is applied to the withdrawal electrodes 155, discharge occurs between the conductive particles to reduce a voltage difference between corresponding withdrawal electrodes 155.

The circuit protection device according to another embodiment in which the plurality of common mode noise filters formed with two inductors and the ESD protection device are combined is connected to the first external electrodes 4000 between a signal input terminal used for an electronic device and a system, the second external electrodes 7000 is connected to a ground terminal to remove the common mode noise and also flow static electricity flowed into the input/output terminal to the ground terminal. In other words, as illustrated in FIG. 4, the common mode noise filter 200 is disposed between the USB connector 30 and the USB chip sets 10 and 20 to efficiently suppress the common mode noise. In addition, when the ESD protection device is connected to the ground terminal between the USB connector 30 and the USB chipsets 10 and 20 to apply a voltage greater than a undesired predetermined voltage to both ends of the circuit protection device, discharge occurs between the ESD protection material and conductive particles to flow a current to the ground terminal and reduce a voltage difference between both ends of a corresponding circuit protection device. At this point, since both ends of the circuit protection device are not conductive, an input signal is delivered to the input/output terminal without distortion at it is. In other words, in the circuit protection device, since corresponding static electricity flows out to the ground through the corresponding circuit protection device, the circuit is protected and at the same time, a signal that a system exchanges is maintained without a change.

Furthermore, it is described that in the circuit protection device according to an embodiment, the plurality of common mode noise filter 2000 is connected to coil patterns formed upper and lower sides thereof to configure the inductors. However, the common mode noise filter 2000 may be configured to allow the coil pattern to surround a magnetic core. In other words, the holes are formed at a central area of the sheets 110 to 140 and a magnetic material is buried in the holes so that a magnetic core is disposed in a vertical direction and the inductor may be implemented to surround the magnetic core in the vertical direction.

A circuit protection device according to embodiment has at least two cutoff frequency characteristics by allowing at least two common mode noise filters to be implemented in one package. A circuit protection device according to embodiment is mounted, for example, in a USB line between a USB 2.0 chipset and USB 3.0 chipset, and a USB connector to be able to suppress noise in the USB line.

Accordingly, compared to a related art in which a circuit protection device in which one common mode noise filter is packaged is installed in each communication line, the number of circuit protection devices can be reduced and accordingly a mount area of the circuit protection device can be reduced. In addition, noises in at least two frequency bands can be suppressed and accordingly the circuit protection device according to embodiments is used for a mobile electronic device such as a smart phone employing various frequency functions, so that quality of the mobile electronic device can be improved.

Although the circuit protection device has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A circuit protection device comprising:
a plurality of sheets stacked in a vertical direction, each of which comprises at least two conductive patterns formed separately from each other in a horizontal direction; and
at least two common mode noise filters disposed in the horizontal direction, each of which comprises at least two conductive patterns connected in the vertical direction.

2. The circuit protection device of claim 1, wherein the conductive pattern comprises a coil pattern, a straight line pattern, and a curved pattern.

3. The circuit protection device of claim 2, wherein the at least two coil patterns formed in the horizontal direction comprises at least two turns.

4. The circuit protection device of claim 3, wherein the plurality of sheets further comprises at least two holes with a conductive material buried therein and at least two first withdrawal electrodes respectively connected to the at least two conductive patterns.

5. The circuit protection device of claim 4, wherein the conductive patterns are connected in the vertical direction through the holes with the conductive material buried therein.

6. The circuit protection device of claim 5, wherein the plurality of sheets comprise first to fourth sheets each of which comprises the at least two holes with the conductive material buried therein, the two at least conductive patterns, and the at least two first withdrawal electrodes,
wherein the conductive patterns on the first sheet are respectively connected to the conductive patterns on the third sheet through the holes formed in the first and second sheets,
the conductive patterns on the second sheet are respectively connected to the conductive patterns on the fourth sheet through the holes formed in the second and third sheets, and
any one of the conductive patterns connected vertically is a coil pattern.

7. The circuit protection device of claim 6, wherein at least any one of the coil patterns comprises a greater number of turns than other coil patterns.

8. The circuit protection device of claim 5, wherein the plurality of sheets comprise first to fourth sheets each of which comprises first to third coil patterns comprising at least two turns,
wherein the first to third coil patterns on the first sheet are respectively connected to the first to third coil patterns on the third sheet through the holes formed in the first and second sheets, and
the first to third coil patterns on the second sheet are respectively connected to the first to third coil patterns on the fourth sheet through the holes formed in the second and third sheets.

9. The circuit protection device of claim 8, wherein the first and third coil patterns comprise an identical number of turns and the second coil pattern comprises a greater number of turns than the first and third coil patterns.

10. The circuit protection device of claim 9, wherein the first to third coil patterns are vertically connected to respectively form first to third common mode noise filters, and the first and third common mode noise filters are connected to a USB 3.0 line connected to a USB 3.0 chipset and the second common mode noise filter is connected to a USB 2.0 line connected to a USB 2.0 chipset.

11. The circuit protection device of claim 10, wherein the first and third common mode noise filters comprise a cutoff frequency of approximately 7 GHz to 9 GHz in a differential mode and the second common mode noise filter comprises a cutoff frequency of approximately 4 GHz to 5 GHz in a differential mode.

12. The circuit protection device of claim 10, wherein the first and third common mode noise filters comprise a cutoff frequency of approximately 2 GHz in a common mode and the second common mode noise filter comprises a cutoff frequency of approximately 1 GHz in a common mode.

13. The circuit protection device of claim 4, further comprising at least two first external electrodes disposed on two opposite side surfaces of a stacked body in which the plurality of sheets are stacked, and connected to the at least two first withdrawal electrodes.

14. The circuit protection device of claim 3, further comprising a magnetic core formed in a center of at least one coil pattern of the common mode noise filter.

15. The circuit protection device of claim 13, further comprising an ESD protection device disposed at a bottom side of the at least one common mode noise filter and configured to protect an ESD.

16. The circuit protection device of claim 15, where the ESD protection device comprises a plurality of holes with an ESD protection material buried therein and at least two second withdrawal electrodes formed in an identical direction to that of the at least two first withdrawal electrodes from the holes.

17. The circuit protection device of claim 16, wherein the ESD protection device further comprises a third withdrawal electrode formed in a perpendicular direction to that of the second withdrawal electrodes.

18. The circuit protection device of claim 17, further comprising second external electrodes disposed on two opposite side surfaces of the stacked body and connected to the third withdrawal electrodes.
